(19) United States
(12) Patent Application Publication
(10) Pub. No.: US 2009/0095221 A1
(43) Pub. Date: Apr. 16, 2009

(54) MULTI-GAS CONCENTRIC INJECTION SHOWERHEAD

(76) Inventors: Alexander TAM, Union City, CA (US); Ronald STEVENS, San Ramon, CA (US); Jacob GRAYSON, Santa Clara, CA (US); David BOUR, Cupertino, CA (US); Sandeep NIJHAWAN, Los Altos, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/873,170

(22) Filed: Oct. 16, 2007

(51) Int. Cl. C23C 16/54

(52) U.S. Cl. 118/715

(57) ABSTRACT

A method and apparatus that may be utilized for chemical vapor deposition and/or hydride vapor phase epitaxial (HVPE) deposition are provided. In one embodiment, a metal organic chemical vapor deposition (MOCVD) process is used to deposit a Group III-nitride film on a plurality of substrates. A Group III precursor, such as trimethyl gallium, trimethyl aluminum or trimethyl indium and a nitrogen-containing precursor, such as ammonia, are separately delivered to a plurality of concentric gas injection ports. The precursor gases are injected into mixing zones where the gases are mixed before entering a processing volume containing the substrates.

### BACKGROUND OF THE INVENTION

1. Field of the Invention

Embodiments of the present invention generally relate to methods and apparatus for chemical vapor deposition (CVD) on a substrate, and, in particular, to a showerhead design for use in metal organic chemical vapor deposition and/or hydride vapor phase epitaxy (HVPE).

2. Description of the Related Art

Group III-V films are finding greater importance in the development and fabrication of a variety of semiconductor devices, such as short wavelength light emitting diodes (LEDs), laser diodes (LDs), and electronic devices including high power, high frequency, high temperature transistors and integrated circuits. For example, short wavelength (e.g., blue/green to ultraviolet) LEDs are fabricated using the Group III-nitride semiconducting material gallium nitride (GaN). It has been observed that short wavelength LEDs fabricated using GaN can provide significantly greater efficiencies and longer operating lifetimes than short wavelength LEDs fabricated using non-nitride semiconducting materials, such as Group II-VI materials.

One method that has been used for depositing Group III-nitrides, such as GaN, is metal organic chemical vapor deposition (MOCVD). This chemical vapor deposition method is generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer, such as GaN, on the substrate surface. The quality of the film depends in part upon deposition uniformity which, in turn, depends upon uniform mixing of the precursors across the substrate.

Multiple substrates may be arranged on a substrate carrier and each substrate may have a diameter ranging from 50 mm to 100 mm or larger. The uniform mixing of precursors over larger substrates and/or more substrates and larger deposition areas is desirable in order to increase yield and throughput. These factors are important since they directly affect the cost to produce an electronic device and, thus, a device manufacturer's competitiveness in the market place.

As the demand for LEDs, LDs, transistors, and integrated circuits increases, the efficiency of depositing high quality Group-III nitride films takes on greater importance. Therefore, there is a need for an improved deposition apparatus and process that can provide uniform precursor mixing and consistent film quality over larger substrates and larger deposition areas.

### SUMMARY OF THE INVENTION

The present invention generally provides improved methods and apparatus for depositing Group III-nitride films using MOCVD and/or HVPE.

One embodiment provides a gas delivery apparatus for deposition on a substrate. The apparatus generally includes a first plenum for a first precursor gas, a second plenum for a second precursor gas, and a plurality of concentrically arranged inner and outer injection holes, the inner injection holes communicating with the first plenum and the outer injection holes communicating with the second plenum.

Another embodiment provides a gas delivery apparatus for deposition on a substrate. The apparatus comprises a plurality of precursor mixing channels defined on a side of the showerhead that faces a substrate processing volume, a plurality of first injection holes through which a first precursor gas is injected into the precursor mixing channels, and a plurality of second injection holes through which a second precursor gas is injected into the precursor mixing channels wherein each of the first injection holes has a second injection hole that is concentrically arranged therewith.

In another embodiment, a gas delivery apparatus for deposition on a substrate is disclosed. The apparatus generally includes a first plenum for a first precursor gas, a plurality of first gas conduits through which the first precursor gas is supplied from the first plenum to a precursor mixing zone, a second plenum for a second precursor gas, and a plurality of second gas conduits through which the second precursor gas is supplied from the second plenum to the precursor mixing zone wherein each of the first gas conduits has a second gas conduit that is concentrically arranged therewith.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic view of a deposition apparatus according to one embodiment of the invention.

FIG. 1B is a detailed cross sectional view of the showerhead assembly shown in FIG. 1A.

FIG. 2A is a detailed cross sectional view of the showerhead assembly shown in FIG. 1B according to one embodiment of the invention.

FIGS. 2B and 2C are cross sectional views of different embodiments for mixing channels and heat exchanging channels.

FIGS. 3A-3D are cross sectional perspective views of additional embodiments of a showerhead assembly according to the present invention.

FIG. 3E is a cross sectional perspective double cut-away view of a showerhead assembly according to one embodiment of the invention.

FIG. 3F is a detailed cross sectional view of the showerhead assembly shown in FIG. 1B according to one embodiment of the invention.

FIG. 4A is a schematic bottom view of the showerhead assembly shown in FIG. 1B according to one embodiment of the present invention.

FIGS. 4B and 4C are schematic bottom views of additional embodiments for the showerhead assembly shown in FIG. 4A according to present invention.

FIG. 5 is a schematic bottom view of the showerhead assembly shown in FIGS. 3C and 3D according to one embodiment of the present invention.

FIG. 6 is a schematic bottom view of additional embodiments of a showerhead assembly according to the present invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

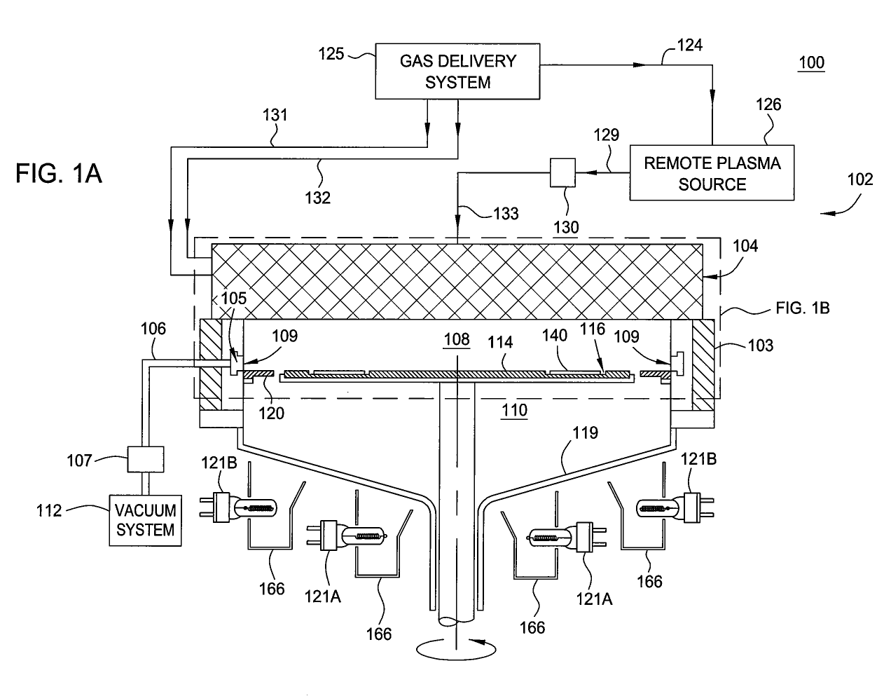

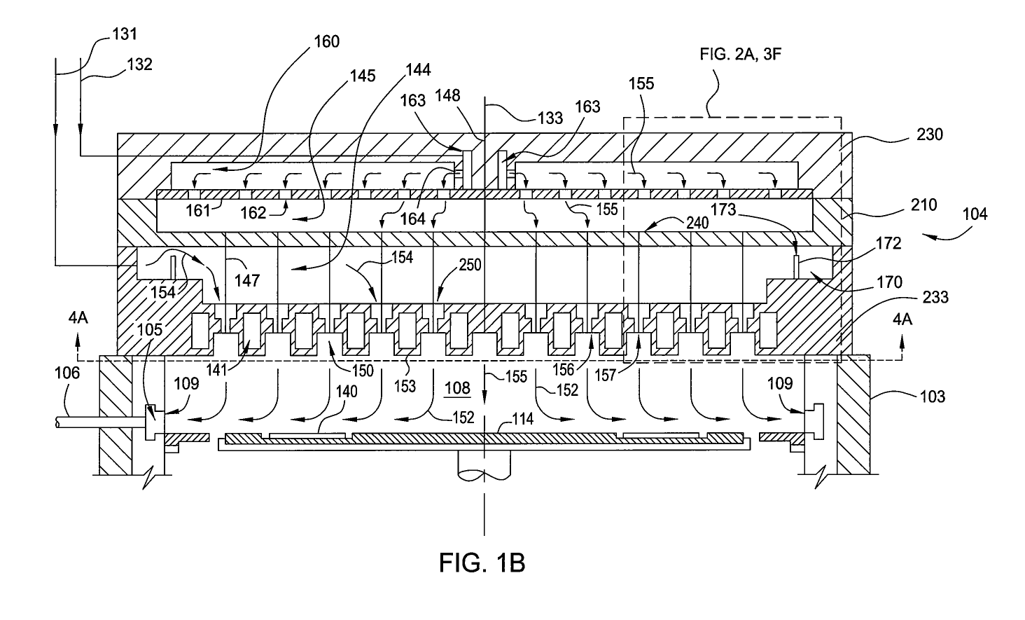

Embodiments of the present invention generally provide a method and apparatus that may be utilized for deposition of Group III-nitride films using MOCVD and/or HVPE. FIG. 1A is a schematic view of a deposition apparatus that may be used to practice the invention according to one embodiment of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

The apparatus 100 shown in FIG. 1A comprises a chamber 102, a gas delivery system 125, a remote plasma source 126, and a vacuum system 112. The chamber 102 includes a chamber body 103 that encloses a processing volume 108. A showerhead assembly 104 is disposed at one end of the processing volume 108, and a substrate carrier 114 is disposed at the other end of the processing volume 108. A lower dome 119 is disposed at one end of a lower volume 110, and the substrate carrier 114 is disposed at the other end of the lower volume 110. The substrate carrier 114 is shown in process position, but may be moved to a lower position where, for example, the substrates 140 may be loaded or unloaded. An exhaust ring 120 may be disposed around the periphery of the substrate carrier 114 to help prevent deposition from occurring in the lower volume 110 and also help direct exhaust gases from the chamber 102 to exhaust ports 109. The lower dome 119 may be made of transparent material, such as high-purity quartz, to allow light to pass through for radiant heating of the substrates 140. The radiant heating may be provided by a plurality of inner lamps 121A and outer lamps 121B disposed below the lower dome 119, and reflectors 166 may be used to help control chamber 102 exposure to the radiant energy provided by inner and outer lamps 121A, 121B. Additional rings of lamps may also be used for finer temperature control of the substrates 140.

The substrate carrier 114 may include one or more recesses 116 within which one or more substrates 140 may be disposed during processing. The substrate carrier 114 may carry six or more substrates 140. In one embodiment, the substrate carrier 114 carries eight substrates 140. It is to be understood that more or less substrates 140 may be carried on the substrate carrier 114. Typical substrates 140 may include sapphire, silicon carbide (SiC), silicon, or gallium nitride (GaN). It is to be understood that other types of substrates 140, such as glass substrates 140, may be processed. Substrate 140 size may range from 50 mm-100 mm in diameter or larger. The substrate carrier 114 size may range from 200 mm-750 mm. The substrate carrier 114 may be formed from a variety of materials, including SiC or SiC-coated graphite. It is to be understood that substrates 140 of other sizes may be processed within the chamber 102 and according to the processes described herein. The showerhead assembly 104, as described herein, may allow for more uniform deposition across a greater number of substrates 140 and/or larger substrates 140 than in traditional MOCVD chambers, thereby increasing throughput and reducing processing cost per substrate 140.

The substrate carrier 114 may rotate about an axis during processing. In one embodiment, the substrate carrier 114 may be rotated at about 2 RPM to about 100 RPM. In another embodiment, the substrate carrier 114 may be rotated at about 30 RPM. Rotating the substrate carrier 114 aids in providing uniform heating of the substrates 140 and uniform exposure of the processing gases to each substrate 140.

The plurality of inner and outer lamps 121A, 121B may be arranged in concentric circles or zones (not shown), and each lamp zone may be separately powered. In one embodiment, one or more temperature sensors, such as pyrometers (not shown), may be disposed within the showerhead assembly 104 to measure substrate 140 and substrate carrier 114 temperatures, and the temperature data may be sent to a controller (not shown) which can adjust power to separate lamp zones to maintain a predetermined temperature profile across the substrate carrier 114. In another embodiment, the power to separate lamp zones may be adjusted to compensate for precursor flow or precursor concentration nonuniformity. For example, if the precursor concentration is lower in a substrate carrier 114 region near an outer lamp zone, the power to the outer lamp zone may be adjusted to help compensate for the precursor depletion in this region.

The inner and outer lamps 121A, 121B may heat the substrates 140 to a temperature of about 400 degrees Celsius to about 1200 degrees Celsius. It is to be understood that the invention is not restricted to the use of arrays of inner and outer lamps 121A, 121B. Any suitable heating source may be utilized to ensure that the proper temperature is adequately applied to the chamber 102 and substrates 140 therein. For example, in another embodiment, the heating source may comprise resistive heating elements (not shown) which are in thermal contact with the substrate carrier 114.

A gas delivery system 125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 102. Different gases, such as precursor gases, carrier gases, purge gases, cleaning/etching gases or others may be supplied from the gas delivery system 125 to separate supply lines 131, 132, and 133 to the showerhead assembly 104. The supply lines 131, 132, and 133 may include shut-off valves and mass flow controllers or other types of controllers to monitor and regulate or shut off the flow of gas in each line.

A conduit 129 may receive cleaning/etching gases from a remote plasma source 126. The remote plasma source 126 may receive gases from the gas delivery system 125 via supply line 124, and a valve 130 may be disposed between the showerhead assembly 104 and remote plasma source 126. The valve 130 may be opened to allow a cleaning and/or etching gas or plasma to flow into the showerhead assembly 104 via supply line 133 which may be adapted to function as a conduit for a plasma. In another embodiment, apparatus 100 may not include remote plasma source 126 and cleaning/etching gases may be delivered from gas delivery system 125 for non-plasma cleaning and/or etching using alternate supply line configurations to shower head assembly 104.

The remote plasma source 126 may be a radio frequency or microwave plasma source adapted for chamber 102 cleaning and/or substrate 140 etching. Cleaning and/or etching gas may be supplied to the remote plasma source 126 via supply line 124 to produce plasma species which may be sent via conduit 129 and supply line 133 for dispersion through showerhead assembly 104 into chamber 102. Gases for a cleaning application may include fluorine, chlorine or other reactive elements.

In another embodiment, the gas delivery system 125 and remote plasma source 126 may be suitably adapted so that precursor gases may be supplied to the remote plasma source 126 to produce plasma species which may be sent through showerhead assembly 104 to deposit CVD layers, such as III-V films, for example, on substrates 140.

A purge gas (e.g., nitrogen) may be delivered into the chamber 102 from the showerhead assembly 104 and/or from inlet ports or tubes (not shown) disposed below the substrate carrier 114 and near the bottom of the chamber body 103. The purge gas enters the lower volume 110 of the chamber 102 and flows upwards past the substrate carrier 114 and exhaust ring 120 and into multiple exhaust ports 109 which are disposed around an annular exhaust channel 105. An exhaust conduit 106 connects the annular exhaust channel 105 to a vacuum system 112 which includes a vacuum pump (not shown). The chamber 102 pressure may be controlled using a valve system 107 which controls the rate at which the exhaust gases are drawn from the annular exhaust channel 105.

FIG. 1B is a detailed cross sectional view of the showerhead assembly shown in FIG. 1A. The showerhead assembly 104 is located near the substrate carrier 114 during substrate 140 processing. In one embodiment, the distance from the showerhead face 153 to the substrate carrier 114 during processing may range from about 4 mm to about 41 mm. In one embodiment, the showerhead face 153 may comprise multiple surfaces of the showerhead assembly 104 which are approximately coplanar and face the substrates 140 during processing.

During substrate 140 processing, according to one embodiment of the invention, process gas 152 flows from the showerhead assembly 104 towards the substrate 140 surface. The process gas 152 may comprise one or more precursor gases as well as carrier gases and dopant gases which may be mixed with the precursor gases. The draw of the annular exhaust channel 105 may affect gas flow so that the process gas 152 flows substantially tangential to the substrates 140 and may be uniformly distributed radially across the substrate 140 deposition surfaces in a laminar flow. The processing volume 108 may be maintained at a pressure of about 760 Torr down to about 80 Torr.

Reaction of process gas 152 precursors at or near the substrate 140 surface may deposit various metal nitride layers upon the substrate 140, including GaN, aluminum nitride (AlN), and indium nitride (InN). Multiple metals may also be utilized for the deposition of other compound films such as AlGaN and/or InGaN. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and a dopant gas may include Bis(cyclopentadienyl)magnesium (Cp₂Mg or (C₅H₅)₂Mg) for magnesium doping.

In one embodiment, the showerhead assembly 104 comprises an annular manifold 170, a first plenum 144, a second plenum 145, a third plenum 160, gas conduits 147, blocker plate 161, heat exchanging channel 141, mixing channel 150, and a central conduit 148. The annular manifold 170 encircles the first plenum 144 which is separated from the second plenum 145 by a mid-plate 210 which has a plurality of mid-plate holes 240. The second plenum 145 is separated from the third plenum 160 by blocker plate 161 which has a plurality of blocker plate holes 162 and the blocker plate 161 is coupled to a top plate 230. The mid-plate 210 includes a plurality of gas conduits 147 which are disposed in mid-plate holes 240 and extend down through first plenum 144 and into bottom plate holes 250 located in a bottom plate 233. The diameter of each bottom plate hole 250 decreases to form a first gas injection hole 156 which is generally concentric or coaxial to gas conduit 147 which forms a second gas injection hole 157. In another embodiment, the second gas injection hole 157 may be offset from the first gas injection hole 156 wherein the second gas injection hole 157 is disposed within the boundary of the first gas injection hole 156. The bottom plate 233 also includes heat exchanging channels 141 and mixing channels 150 which comprise straight channels which are parallel to each other and extend across showerhead assembly 104.

The showerhead assembly 104 receives gases via supply lines 131, 132, and 133. In another embodiment, each supply line 131, 132 may comprise a plurality of lines which are coupled to and in fluid communication with the showerhead assembly 104. A first precursor gas 154 and a second precursor gas 155 flow through supply lines 131 and 132 into annular manifold 170 and top manifold 163. A non-reactive gas 151, which may be an inert gas such as hydrogen (H₂), nitrogen (N₂), helium (He), argon (Ar) or other gases and combinations thereof, may flow through supply line 133 coupled to a central conduit 148 which is located at or near the center of the showerhead assembly 104. The central conduit 148 may function as a central inert gas diffuser which flows a non-reactive gas 151 into a central region of the processing volume 108 to help prevent gas recirculation in the central region. In another embodiment, the central conduit 148 may carry a precursor gas.

In yet another embodiment, a cleaning and/or etching gas or plasma is delivered through the central conduit 148 into the chamber 102. The central conduit 148 is adapted to disperse the cleaning and/or etching gas or plasma inside chamber 102 to provide more effective cleaning. In other embodiments, the apparatus 100 is adapted to deliver cleaning and/or etching gas or plasma into chamber 102 through other routes, such as the first and second gas injection holes 156, 157. In one embodiment, a fluorine or chlorine based plasma is used for etching or cleaning. In other embodiments, halogen gases, such as Cl₂, Br, and I₂, or halides, such as HCl, HBr, and HI, are used for non-plasma etching.

In another embodiment, the central conduit 148 may function as a metrology port, and a metrology tool (not shown) may be coupled to the central conduit 148. The metrology tool may be used to measure various film properties, such as thickness, roughness, composition, or other properties. In another embodiment, the central conduit 148 may be adapted to function as a port for a temperature sensor, such as a pyrometer or thermocouple.

The first precursor gas 154 flows into annular manifold 170 and through gap 173 formed by a restricting wall 172 disposed at the inner diameter of the annular manifolds 170. The restricting wall 172 may provide more uniform gas distribution in the azimuthal direction of annular manifold 170 as first precursor gas 154 flows into first plenum 144 which is in fluid communication with first gas injection holes 156. The second precursor gas 155 flows into top manifold 163 and is dispersed radially through holes 164 into third plenum 160. The second precursor gas 155 then flows through blocker plate holes 162 into second plenum 145 and into gas conduits 147 which are fluid communication with second gas injection holes 157. The first plenum 144 is not in fluid communication with the second or third plenums 145, 160 so that the first and second precursor gases 154, 155 remain isolated until injected into the chamber 102.

The first and second precursor gases 154, 155 flow from into first and second gas injection holes 156, 157 and then into a mixing channel 150 where the first and second precursor gases 154, 155 mix to form process gas 152 which then flows into processing volume 108. In one embodiment, a carrier gas, which may comprise nitrogen gas (N₂) or hydrogen gas (H₂) or an inert gas, is mixed with the first and second precursor gases 154, 155 prior to delivery to the showerhead assembly 104.

In one embodiment, the first precursor gas 154 which is delivered to first plenum 144 may comprise a Group V precursor, and second precursor gas 155 which is delivered to second plenum 145 may comprise a Group III precursor. In another embodiment, the precursor delivery may be switched so that the Group V precursor is routed to second plenum 145 and the Group III precursor is routed to first plenum 144. The choice of first or second plenum 144, 145 for a given precursor may be determined in part by the distance of the plenum from the heat exchanging channels 141 and the desired temperature ranges which may be maintained for each plenum and the precursor therein.

The Group III precursor may be a metal organic (MO) precursor such as trimethyl gallium (“TMG”), trimethyl aluminum (“TMAI”), and/or trimethyl indium (“TMI”), but other suitable MO precursors may also be used. The Group V precursor may be a nitrogen precursor, such as ammonia (NH₃). In one embodiment, a single MO precursor, such as TMG, may be delivered to either first plenum 144 or second plenum 145. In another embodiment, two or more MO precursors, such as TMG and TMI, may be mixed and delivered to either first plenum 144 or second plenum 145.

Disposed adjacent to the first and second gas injection holes 156, 157 and mixing channels 150 are heat exchanging channels 141 through which a heat exchanging fluid flows to help regulate the temperature of the showerhead assembly 104. Suitable heat exchanging fluids include water, water-based ethylene glycol mixtures, a perfluoropolyether (e.g., Galden® fluid), oil-based thermal transfer fluids, or similar fluids. The heat exchanging fluid may be circulated through a heat exchanger (not shown) to raise or lower the temperature of the heat exchanging fluid as required to maintain the temperature of the showerhead assembly 104 within a desired temperature range. In one embodiment, the heat exchanging fluid is maintained within a temperature range of about 20 degrees Celsius to about 120 degrees Celsius. In another embodiment, the heat exchanging fluid may be maintained within a temperature range of about 100 degrees Celsius to about 350 degrees Celsius. In yet another embodiment, the heat exchanging fluid may be maintained at a temperature of greater than 350 degrees Celsius. The heat exchanging fluid may also be heated above its boiling point so that the showerhead assembly 104 may be maintained at higher temperatures using readily available heat exchanging fluids. Also, the heat exchanging fluid may be a liquid metal, such as gallium or gallium alloy.

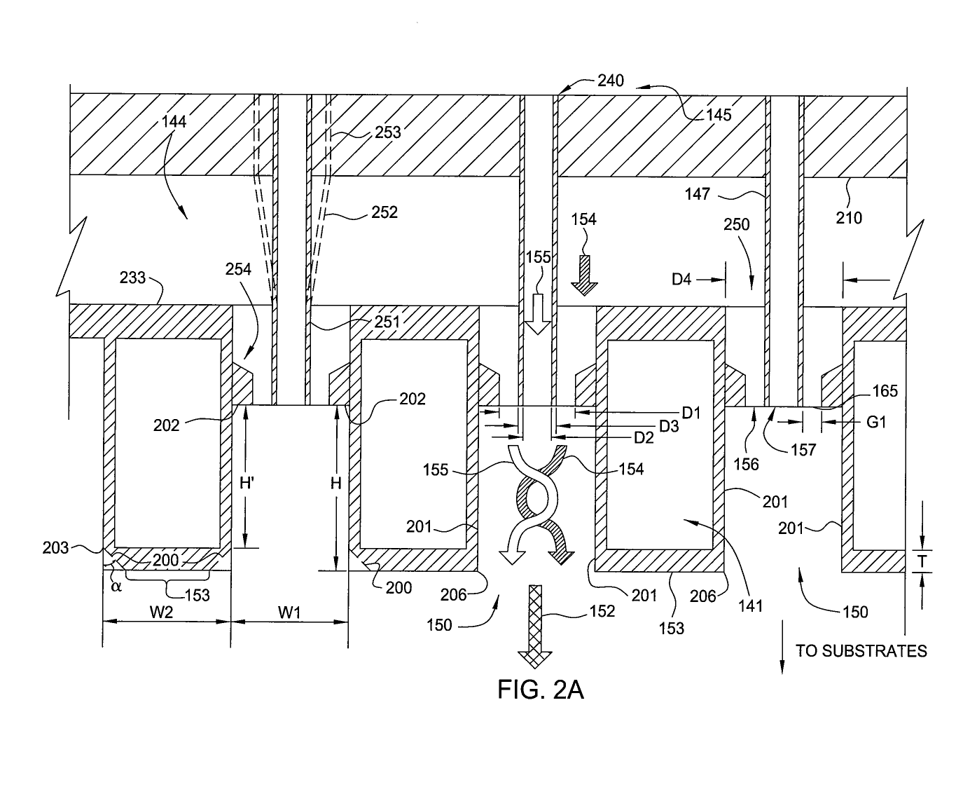

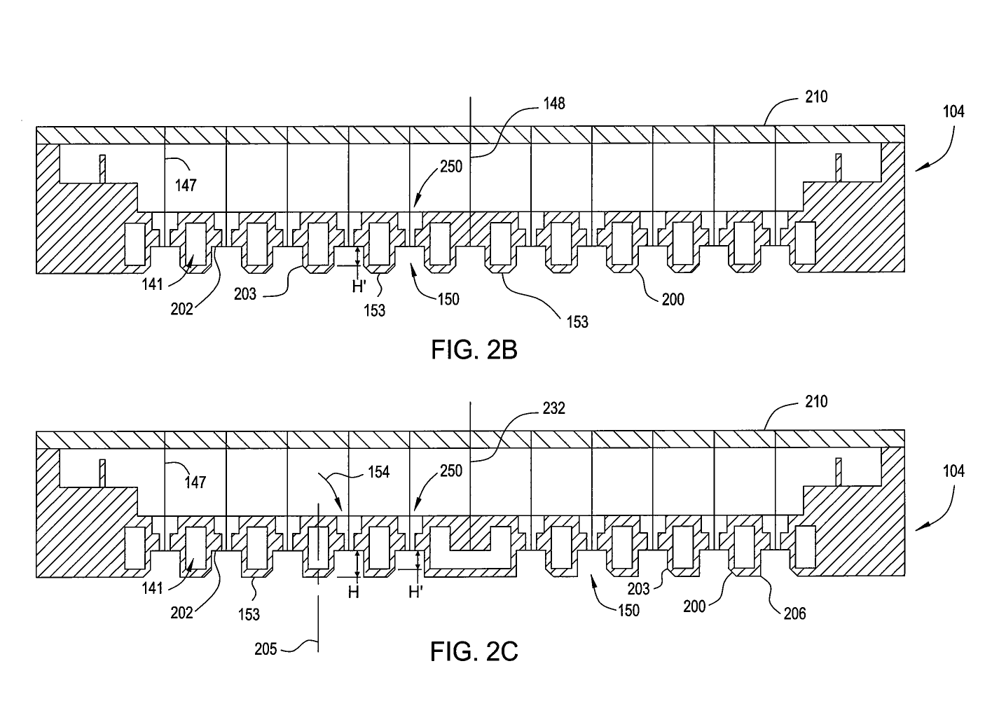

The flow rate of the heat exchanging fluid may also be adjusted to help control the temperature of the showerhead assembly 104. Additionally, the wall thicknesses of the heat exchanging channels 141 are designed to facilitate temperature regulation of various showerhead surfaces. For example, the wall thickness T (see FIG. 2A) of the showerhead face 153 may be made thinner to increase the rate of thermal transfer through the wall and thereby increase the cooling or heating rate of the showerhead face 153.

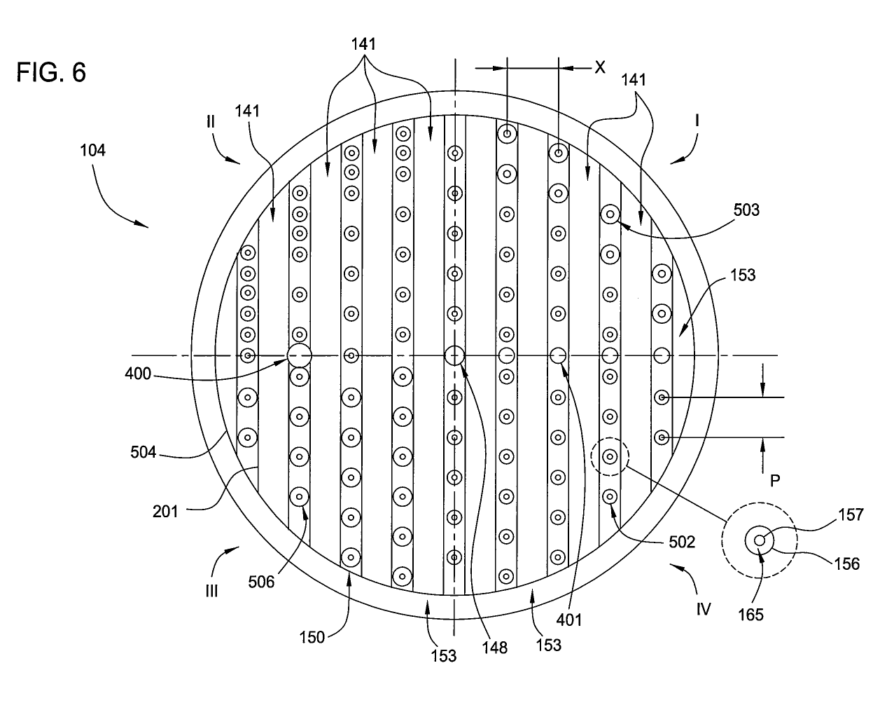

Control of temperature for various showerhead assembly 104 features, such as mixing channels 150 and showerhead face 153, is desirable to reduce or eliminate formation of condensates on the showerhead assembly 104 as well as reduce gas phase particle formation and prevent the production of undesirable precursor reactant products which may adversely affect the composition of the film deposited on the substrates 140. In one embodiment, one or more thermocouples or other temperature sensors are disposed in proximity to showerhead face 153 to measure the showerhead temperature. The one or more thermocouples or other temperature sensors are disposed near central conduit 148 and/or outer perimeter 504 (see FIG. 6) of showerhead assembly 104. In another embodiment, one or more thermocouples or other temperature sensors are disposed in proximity to heat exchanging channel 141 inlets and outlets. In other embodiments, the temperature sensor is located in proximity to other showerhead assembly 104 features. In other embodiments, the temperature sensor is located in proximity to other showerhead assembly 104 features.

The temperature data measured by the one or more thermocouples or other temperature sensors may be sent to a controller (not shown) which may adjust the heat exchanging fluid temperature and flow rate to maintain the showerhead temperature within a predetermined range. In one embodiment, the showerhead temperature may be maintained at about 50 degrees Celsius to about 350 degrees Celsius. In another embodiment, the showerhead temperature may be maintained at a temperature of greater than 350 degrees Celsius.

FIG. 2A is a detailed cross sectional view of the showerhead assembly shown in FIG. 1B according to one embodiment of the invention. The first and second precursor gases 154, 155 flow from bottom plate holes 250 and gas conduits 147 into first and second gas injection holes 156, 157 and then into mixing channel 150. The first gas injection hole 156 has diameter D1, and the second gas injection hole 157 has diameter D2. The gas conduit 147 is a tube having an inside diameter D2 and outside diameter D3 near first gas injection hole 156. In one embodiment, the gas conduit 147 is a cylindrical tube. In another embodiment, gas conduit 147 may comprise multiple tubes having different cross sections. For example, gas conduit 147 may comprise conduit tubes 251, 252, and 253 (see dashed lines) having different inside and outside diameters wherein the conduit tubes 251, 252, 253 are coupled together (e.g., brazed or welded) to form a single, integral tube. In yet another embodiment, gas conduit 147 may comprise one or more tubes which have been swaged and each tube may have varying cross sectional diameters. In one embodiment, the gas conduit 147 is funnel shaped. In other embodiments, the gas conduit 147 may have other shapes.

A first end of gas conduit 147 is disposed in mid-plate hole 240 and the first end of gas conduit 147 is suitably coupled (e.g., brazed) to mid-plate 210 so that a fluid seal is formed between the gas conduit 147 and mid-plate 210. A second end of gas conduit 147 is disposed within bottom plate hole 250 such that the gas conduit 147 is concentric or coaxial to the bottom plate hole 250 and first gas injection hole 156 so that the second end of gas conduit 147 forms a second gas injection hole 157 which is concentric or coaxial to first gas injection hole 156. In one embodiment, the first and second gas injection holes 156, 157 extend to a common surface such as channel surface 202 and are approximately coplanar. In another embodiment, the second end of gas conduit 147 may be disposed slightly outside the plane of the first gas injection hole 156 so that the first and second gas injection holes 156, 157 are not coplanar.

The bottom plate hole 250 has a diameter D4 which extends through bottom plate 233. In one embodiment, diameter D4 may range from about 1 millimeter (mm) to about 7 millimeters (mm). A ring insert 254 having diameter D1 is disposed within bottom plate hole 250 to form first gas injection hole 156. The ring insert 254 may be a tube which extends partially or fully along the length of bottom plate hole 250. The ring insert 254 is coupled (e.g., press fit or brazed or welded) to bottom plate hole 250 so that a fluid seal is formed between bottom plate hole 250 and ring insert 254. In another embodiment, the ring insert 254 may be replaced by a similar ring feature which is machined (e.g., a counterbore) into bottom plate hole 250. In yet another embodiment, the bottom plate hole 250 may be suitably sized to form first gas injection hole 156 such that diameter D4 equals diameter D1.

The second end of gas conduit 147 is disposed within first gas injection hole 156 and an injection hole gap 165 through which the first precursor gas 154 flows is formed between gas conduit 147 and first gas injection hole 156. The injection hole gap 165 is annular in shape and has a gap size G1. The hole diameter D1, inside diameter D2, outside diameter D3, and gap size G1 may be selected to facilitate laminar gas flow, avoid gas recirculation, and help provide the desired gas flow rates for first and second precursor gases 154, 155. In one embodiment, the gas flow rates through each first and second gas injection hole 156, 157 may be approximately equal. In one embodiment, the first gas injection hole 156 has diameter D1 which may range from about 0.7 mm to about 1.5 mm; the inside diameter D2 of gas conduit 147 may range from about 0.2 mm to about 0.8 mm; the outside diameter D3 of gas conduit 147 may range from about 0.4 mm to about 1 mm; and the gap size G1 may range from about 0.05 mm to about 0.5 mm.

The first and second precursor gases 154, 155 flow into mixing channel 150 and mix to form process gas 152. The mixing channel 150 allows the first and second precursor gases 154, 155 to mix partially or fully before entering the processing volume 108, where additional precursor mixing may occur as the process gas 152 flows towards the substrates 140. Additionally, the proximity of the concentric injection hole gap 165 and second gas injection hole 157 may facilitate quicker and more complete mixing of the precursor gases within the mixing channel 150. This “pre-mixing” of the first and second precursor gases 154, 155 may provide more complete and uniform mixing of the precursors before the process gas 152 reaches the substrates 140, resulting in higher deposition rates and improved film qualities.

Vertical walls 201 of the mixing channel 150 may be formed by the outer or exterior walls of heat exchanging channels 141 which are adjacent to the mixing channel 150. In one embodiment, the mixing channel 150 comprises exterior walls formed by vertical walls 201 which are substantially parallel to each other. The height H of the mixing channel 150 is measured from channel surface 202 to a corner 206 where the mixing channel 150 terminates. In one embodiment, the height H of the mixing channel 150 may range from about 3 mm to about 15 mm. In another embodiment, height H of the mixing channel 150 may exceed 15 mm. In one embodiment, the width W1 of the mixing channel 150 may range from about 1 mm to about 5 mm, and the width W2 of the heat exchanging channel 141 may be from about 2 mm to about 8 mm.

In another embodiment, corner 206 is replaced by a chamfer, bevel, radius, or other geometrical feature to produce diverging walls 200 (indicated by dashed lines) at one end of a mixing channel 150 having a height H′ measured from channel surface 202 to corner 203 where the mixing channel 150 terminates. The distance between the diverging walls 200 increases in the direction of the substrates 140 so that the surface area of the showerhead face 153 is reduced and the gas flow path widens as the process gas 152 flows downstream. The reduction in surface area of the showerhead face 153 may help reduce gas condensation, and the diverging walls 200 may help reduce gas recirculation as the process gas 152 flows past the heat exchanging channels 141. A diverging angle a may be selected to increase or decrease the surface area of the showerhead face 153 and help reduce gas recirculation. In one embodiment, the angle α is zero degrees. In another embodiment, the angle α is 45 degrees. In another embodiment, a heat exchanging channel 141 may have a corner 206 on one side of the channel and a diverging wall 200 on the opposite side of the channel.

FIGS. 2B and 2C are cross sectional views of different embodiments for mixing channels 150 and heat exchanging channels 141 of showerhead assembly 104. FIG. 2B is an embodiment which places a chamfer, bevel, radius, or other geometrical feature at corner 206 of heat exchanging channels 141 to produce diverging walls 200 at one end of the mixing channel 150 which has height H′ as measured from corner 203 to channel surface 202.

FIG. 2C shows another embodiment in which vertical walls 201 and diverging walls 200 are both used and are located asymmetrically with respect to central planes 205 of heat exchanging channels 141. This asymmetric wall configuration may minimize recirculation as process gas 152 flows from showerhead assembly 104 to substrates 140 to annular exhaust channel 105. Heights H′ and H are measured from channel surface 202 to corners 203 and 206 respectively. The heights H′ and H may be used to characterize an effective length for the mixing channel 150.

FIG. 2C shows another embodiment of the showerhead assembly 104 shown in FIG. 1B. Central conduit 148 may be replaced by a heat exchanging fluid conduit 232 disposed at or near the center of showerhead assembly 104 and supply line 133 may be adapted to flow a heat exchanging fluid. The heat exchanging fluid conduit 232 may function as a supply or return line for heat exchanging channels 141.

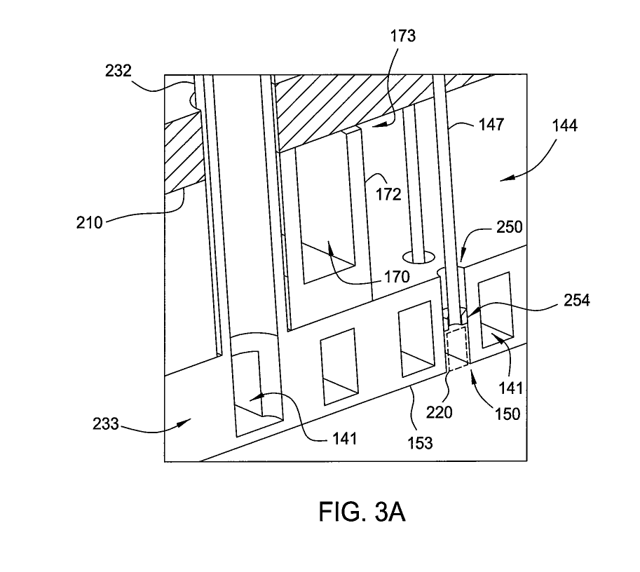

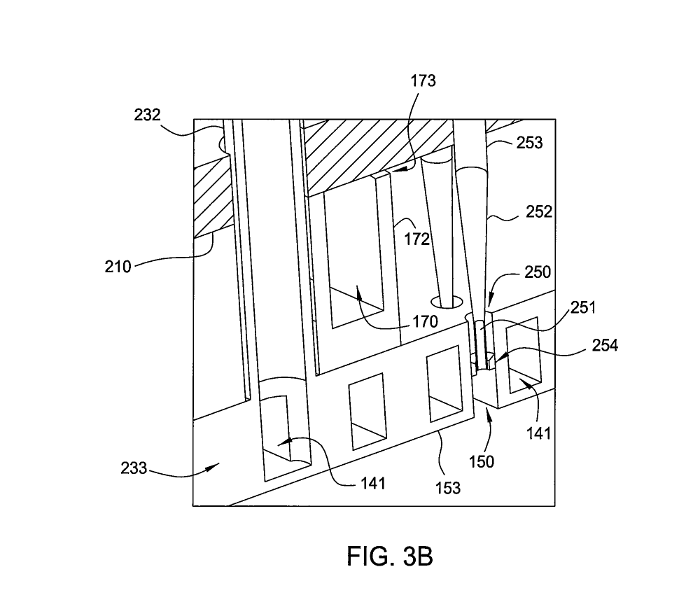

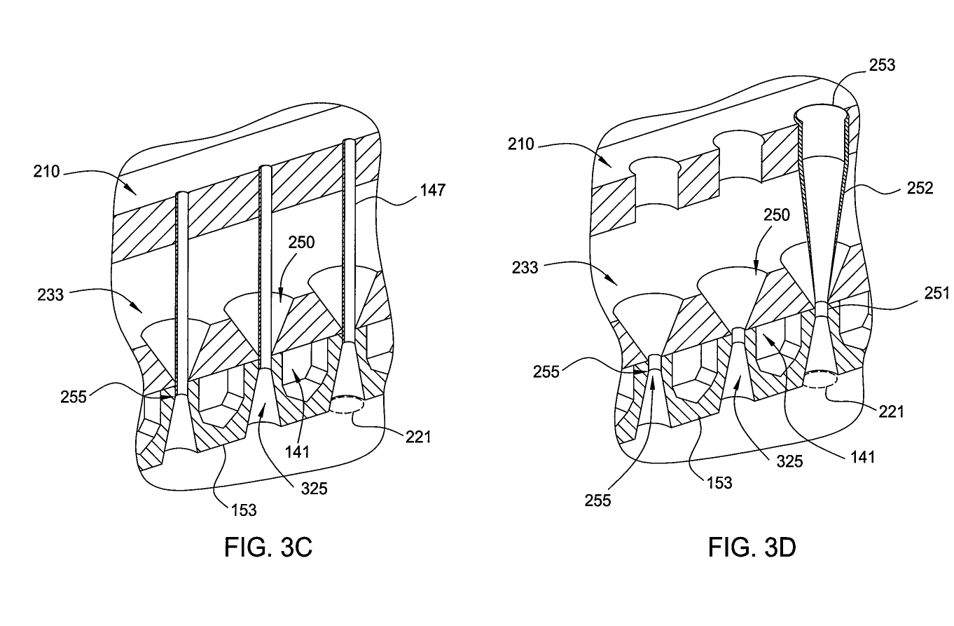

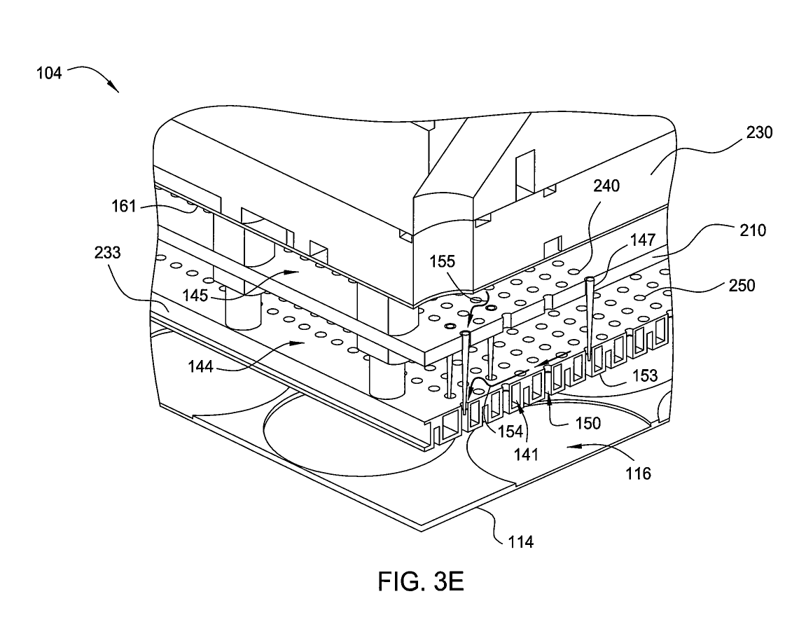

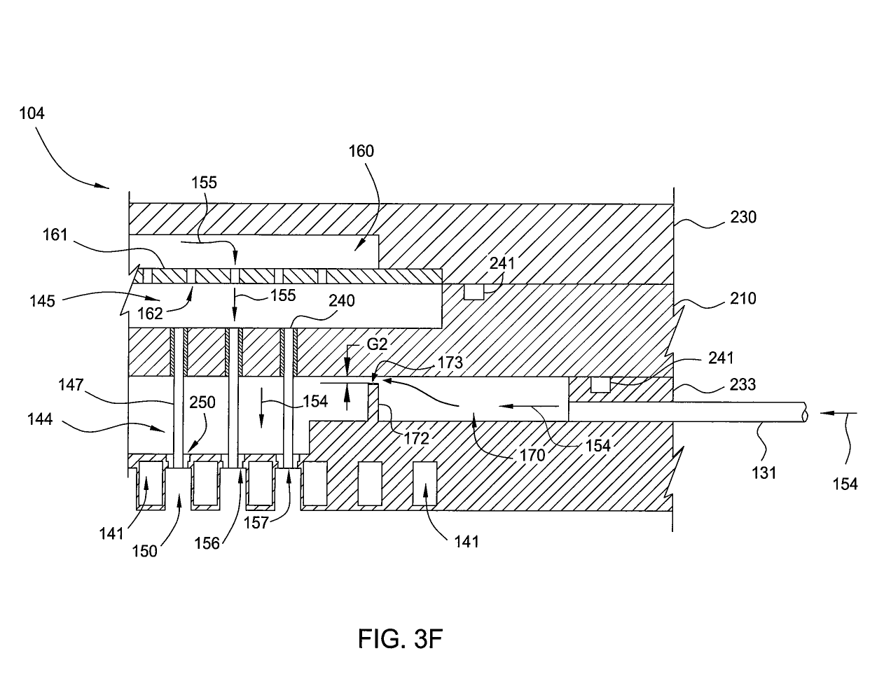

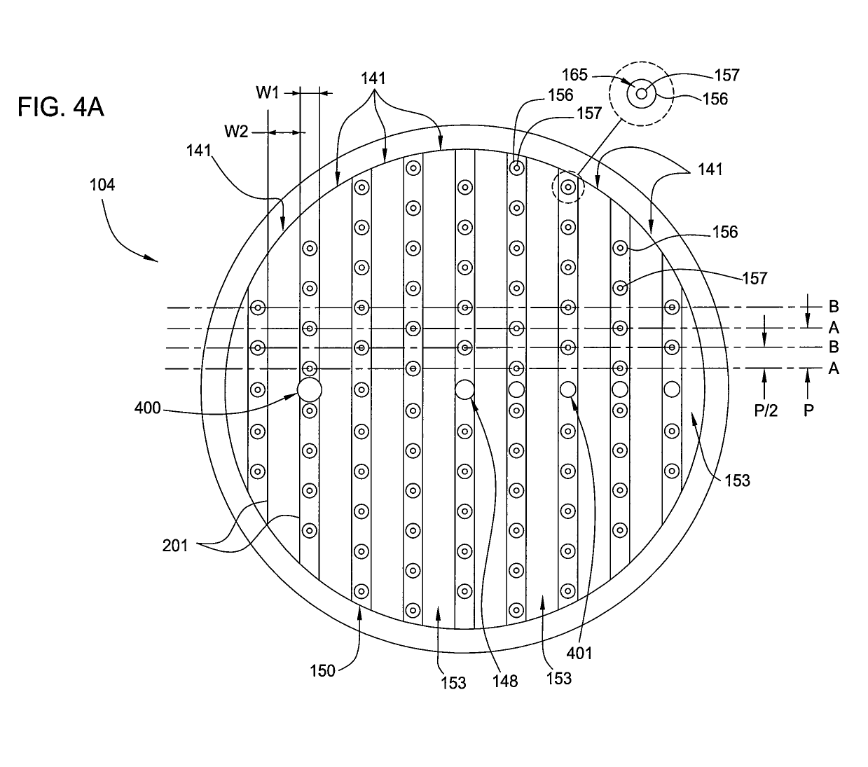

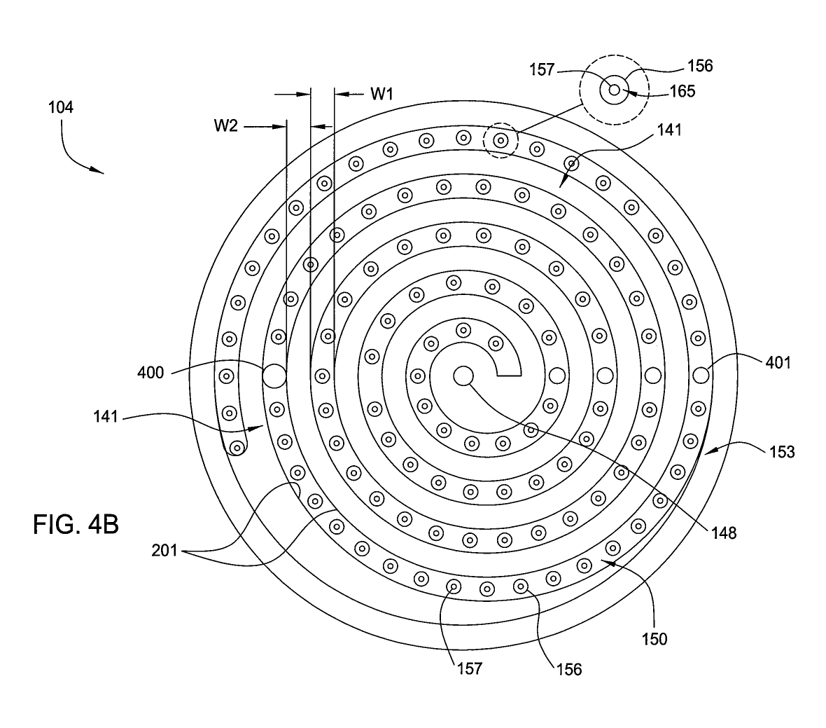

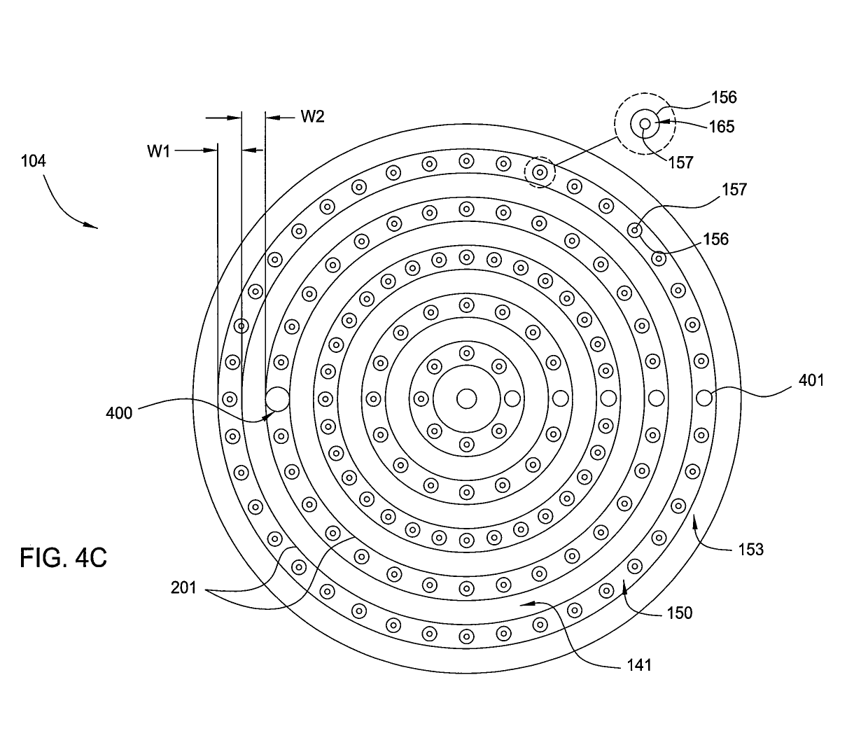

FIGS. 3A-3D are cross sectional perspective views of additional embodiments of a showerhead assembly according to the present invention. FIG. 3A shows mixing channels 150 and heat exchanging channels 141. These channels are straight and parallel to each other and extend linearly across the bottom face of the showerhead as shown in FIG. 4A. Heat exchanging fluid conduit 232 is coupled to heat exchanging channel 141 and extends upwards through mid-plate 210. Sealing devices (not shown) such as o-rings may be disposed around the heat exchanging fluid conduit 232 so that first plenum 144 is not in fluid communication with second or third plenums 145, 160. Annular manifold 170 having restricting wall 172 and gap 173 is disposed around the periphery of first plenum 144. Gas conduits 147 extend from mid-plate 210 and are concentric or coaxial to bottom plate holes 250 and a second end of each gas conduit 147 is disposed within ring insert 254 to form injection hole gap 165 which is concentric to second gas injection hole 157. In one embodiment, the gas conduits 147 may comprise quartz or other materials such as 316L stainless steel, Inconel®, Hastelloy®, electroless nickel plated aluminum, pure nickel, and other metals and alloys resistant to chemical attack. The injection hole gap 165 and second gas injection hole 157 are in fluid communication with mixing channel 150 which has a rectangular cross 220 which extends the length of the mixing channel 150.

FIG. 3B shows another embodiment of the gas conduits 147 shown in FIG. 3A. Gas conduit 147 is funnel shaped and comprises conduit tubes 251, 252, and 253 having different inside and outside diameters wherein the conduit tubes 251, 252, 253 are coupled together (e.g., brazed or welded) to form a single, integral tube. In another embodiment, gas conduit 147 may comprise one or more tubes which have been swaged and each tube may have varying cross sectional diameters.

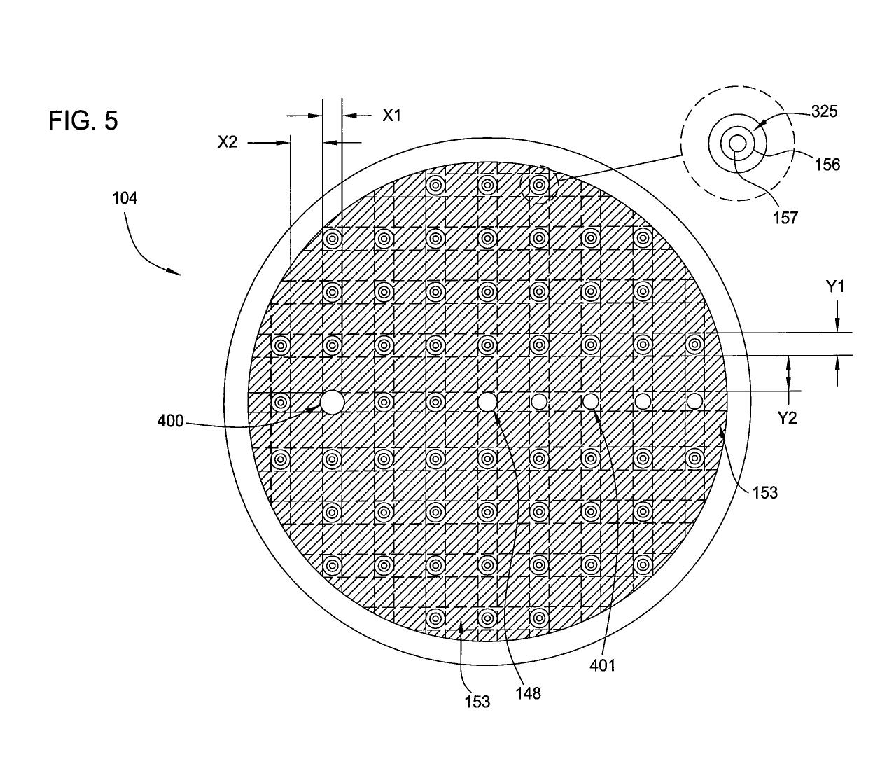

FIGS. 3C and 3D show additional embodiments for bottom plate holes 250, mixing zones 325 and heat exchanging channels 141. FIG. 3C shows cylindrical shaped gas conduits 147 which extend into bottom plate holes 250 which are conical or funnel shaped. The bottom plate 233 may comprise two or more plates which are coupled together wherein one of the plates includes heat exchanging channels 141. A lower portion 255 of the bottom plate holes 250 may have a cylindrical shape. The gas conduits 147 are concentric or coaxial to bottom plate holes 250 and extend into the bottom plate holes 250 to form injection hole gaps 165 and second gas injection holes 157 which are in fluid communication with mixing zones 325 which are disposed between heat exchanging channels 141. The mixing zones 325 are conical in shape with circular cross sections 221. In one embodiment, the heat exchanging channels 141 comprise an x-y grid (see FIG. 5) wherein heat exchanging fluid may flow between mixing zones 325 which are also disposed in a grid pattern. FIG. 3D shows another embodiment for gas conduit 147 wherein the gas conduit 147 is funnel shaped.

FIG. 3E is a cross sectional perspective double cut-away view of a showerhead assembly according to one embodiment of the invention. The showerhead assembly 104 comprises a top plate 230, blocker plate 161, mid-plate 210 and bottom plate 233 which are coupled together. The bottom plate 233 comprises heat exchanging channels 141 and mixing channels 150 which comprise straight channels which are parallel to each other and extend across and over substrate carrier 114.

A second precursor gas 155 is delivered to second plenum 145 via blocker plate 161. The second precursor gas 155 then flows into a plurality of mid-plate holes 240 disposed in mid-plate 210 and into gas conduits 147 which are in fluid communication with mixing channels 150. A gas conduit 147 is disposed in each mid-plate hole 240 but for clarity only a few gas conduits 147 are shown. In one embodiment, the second precursor gas 155 may be a metal organic precursor, such as TMG.

As shown in FIG. 3E, each gas conduit 147 is funnel shaped. In another embodiment, the gas conduit 147 may be cylindrical in shape. A first end of each gas conduit 147 is disposed in a mid-plate hole 240 and the first end of gas conduit 147 is suitably coupled (e.g., brazed and/or press fit) to mid-plate 210 so that a fluid seal is formed between the gas conduit 147 and mid-plate 210. A second end of each gas conduit 147 is disposed within bottom plate hole 250 such that the gas conduit 147 is concentric or coaxial to the bottom plate hole 250.

The first plenum 144 contains first precursor gas 154 which flows into a plurality of bottom plate holes 250 which are in fluid communication with mixing channels 150. In one embodiment, the first precursor gas 154 may be a nitrogen precursor, such as ammonia.

FIG. 3F is a detailed cross sectional view of the showerhead assembly shown in FIG. 1 B according to one embodiment of the invention. First precursor gas 154 is delivered by supply line 131 into annular manifold 170 which is disposed at the periphery of first plenum 144. The gas then flows through a gap 173 disposed at the top of restricting wall 172 which is located at the inner diameter of annular manifold 170 and into first plenum 144 and bottom plate holes 250. The gap 173 may be sufficiently narrow to allow the annular manifold 170 to fill and acquire a more uniform gas distribution in the azimuthal direction as precursor gas flows into first plenum 144. Additionally, the gap 173 has a gap size G2 which may be sized to control the gas flow rate into the plenum and promote laminar gas flow. In one embodiment, gap size G2 may range from about 0.5 mm to about 1.5 mm.

Second precursor gas 155 flows from third plenum 160 into blocker plate holes 162 and into second plenum 145 where the gas flows into a plurality of mid-plate holes 240 and into gas conduits 147. The first and second precursor gases 154, 155 are injected into mixing channels 150 through concentric first and second gas injection holes 156, 157.

FIG. 3F also shows a showerhead assembly 104 which comprises multiple plates. A top plate 230, mid-plate 210, and bottom plate 233 are coupled together to form the showerhead assembly 104 and bottom plate 233 may comprise two or more plates wherein one of the plates includes heat exchanging channels 141. One or more o-rings (not shown) and o-ring grooves 241 or other sealing devices may be disposed throughout the assembly to enable fluid isolation of various showerhead components such as plenums and coolant channels.

The showerhead assembly 104 may be designed so that it may be disassembled to facilitate cleaning and part replacement. Materials which may be compatible with the processing environment and may be used for the showerhead assembly 104 include 316L stainless steel, Inconel®, Hastelloy®, electroless nickel plated aluminum, pure nickel, molybdenum, tantalum and other metals and alloys resistant to degradation and deformation from high temperatures, thermal stress, and reaction from chemical precursors. To help reduce assembly complexity and ensure isolation of the different gases and liquids which flow through the assembly, electroforming may also be used to fabricate various parts of the showerhead assembly 104. Such electroformed parts may reduce the number of parts and seals required to isolate the different gases and liquids within the assembly. Additionally, electroforming may also help reduce fabrication costs for those parts which have complex geometries.

FIG. 4A is a schematic bottom view of the showerhead assembly shown in FIG. 1B according to one embodiment of the present invention. The straight channel geometry of showerhead assembly 104 is reflected by the linear arrangement of the concentric first and second gas injection holes 156 and 157 and injection hole gaps 165 which are disposed at the bottom of showerhead assembly 104. Mixing channels 150 comprise straight and parallel channels which are recessed from showerhead face 153 and have vertical walls 201. Heat exchanging channels 141 comprise straight and parallel channels having width W2 and are disposed between the mixing channels 150 having width W1. The mixing channels 150 are parallel to the heat exchanging channels 141.

As shown in FIG. 4A, the locations of the concentric gas injection holes may be staggered from one mixing channel 150 to the next. A pitch P is the shortest distance between concentric gas injection holes along the same mixing channel 150 as indicated by the distances between dashed lines A and between dashed lines B. The vertical distance (as measured in the direction of mixing channels 150) between concentric gas injection holes along adjacent mixing channels 150 may be reduced to P/2 by staggering the gas injection holes, as indicated by the distance between dashed line A and dashed line B. Such staggering of the gas injection holes may provide more uniform gas distribution over substrate carrier 114 and substrates 140. In another embodiment, the concentric gas injection holes are not staggered and P/2 is replaced by P.

A central conduit 148 is located at or near the center of the showerhead assembly 104, and several embodiments for the central conduit 148 have been previously described herein. One or more ports 400 and 401 may be disposed about the central conduit 148, and the port 400 and 401 diameters may be the same or different depending upon the intended function of each port 400 and 401. In one embodiment, the ports 400 and/or 401 may be used to house temperature sensors such as pyrometers or thermocouples to measure substrate temperature and/or other temperatures, such as the temperature of the showerhead face 153. In one embodiment, the ports 400 and 401 may be disposed on the showerhead assembly 104 to avoid intersecting with the heat exchanging channels 141.

In another embodiment, the ports 400 and/or 401 may be used as metrology ports and may be coupled to one or more metrology tools (not shown). The metrology tool may be used to measure various film properties, such as such as real time film growth, thickness, roughness, composition, or other properties. One or more ports 400 and 401 may also be angled to enable use of a metrology tool, such as for reflectance measurements which may require an angled emitter and receiver for a reflected laser beam, for example.

Each port 400 and 401 may also be adapted to flow a purge gas (which may be an inert gas, such as nitrogen or argon) to prevent condensation on devices within ports 400 and 401 and enable accurate in situ measurements. The purge gas may have annular flow around a sensor, probe, or other device which is disposed inside tube sensor 301 and adjacent to port 400, 401. In another embodiment, the ports 400, 401 may have a diverging nozzle design so that the purge gas flow path widens as the gas moves downstream towards substrates 140. The diverging nozzle may be a countersink, chamfer, radius or other feature which widens the gas flow path. In one embodiment, the purge gas may have a flow rate of about 50 sccm (standard cubic centimeters per minute) to about 500 sccm.

FIGS. 4B and 4C are schematic bottom views of additional embodiments for the showerhead assembly shown in FIG. 4A according to present invention. FIG. 4B shows another embodiment of the showerhead assembly 104 wherein the straight channel geometry is replace by spiral channels. The mixing channels 150 and heat exchanging channels 141 comprise spiral channels which “spiral out” from the center of the showerhead assembly 104. Concentric first and second gas injection holes 156 and 157 and injection hole gaps 165 are disposed at the bottom of showerhead assembly 104 along a spiral mixing channel 150 having width W1 measured to vertical walls 201. The spiral mixing channel 150 is recessed from showerhead face 153 and is adjacent to spiral heat exchanging channel 141 having width W2 and the mixing channel 150 and heat exchanging channel 141 alternate along a radius of the showerhead assembly 104. Embodiments for central conduit 148 and ports 400, 401 have been previously described herein. While spiral channels have been disclosed, other arrangements, such as concentric channels, may also be used for the heat exchanging channels 141 and mixing channels 150.

FIG. 4C is schematic bottom view of another embodiment for showerhead assembly 104. The mixing channels 150 and heat exchanging channels 141 comprise concentric channels disposed at the bottom of showerhead assembly 104. Concentric first and second gas injection holes 156 and 157 and injection hole gaps 165 are disposed along concentric mixing channels 150 having width W1 measured to vertical walls 201. The concentric mixing channels 150 are recessed from showerhead face 153 and are adjacent to concentric heat exchanging channel 141 having width W2 and the mixing channel 150 and heat exchanging channel 141 alternate along a radius of the showerhead assembly 104.

FIG. 5 is a schematic bottom view of the showerhead assembly shown in FIGS. 3C and 3D according to one embodiment of the present invention. In this embodiment, mixing channels 150 are replaced by mixing zones 325 which are conical in shape and have circular cross sections 221. First and second gas injection holes 156 and 157 and injection hole gaps 165 are concentric to the mixing zones 325 which are arranged in an x-y grid pattern along showerhead face 153.

Heat exchanging channels 141 are disposed between the mixing zones 325 such that the heat exchanging channels 141 form an x-y grid pattern (see cross hatching) having widths X2 in the x-direction and widths Y2 in the y-direction. The widths X2 and Y2 indicate approximate widths for the heat exchanging channels 141 which carry heat exchanging fluid. Widths X1 and Y1 indicate approximate dimensions for areas which include mixing zones 325 but lie outside heat exchanging channels 141. In one embodiment, the widths X1, X2, Y1, and Y2 may be approximately equal. Embodiments for central conduit 148 and ports 400, 401 have been previously described herein.

FIG. 6 is a schematic bottom view of additional embodiments for a showerhead assembly 104 according to the present invention. A plurality of concentric gas injection holes 502 are in fluid communication with straight mixing channels 150 which are disposed between heat exchanging channels 141. The concentric gas injection holes 502 may comprise first and second gas injection holes 156 and 157 and injection hole gaps 165 with diameter D1, diameter D2, and gap size G1 respectively.

In one embodiment, as shown in quadrant IV, the same-sized gas injection holes 502 may be used across showerhead face 153. The term “same-sized” means that the values for D1, D2, and G1 do not change from one concentric gas injection hole 502 to another. The showerhead assembly 104 may be suitably designed to help achieve proportional gas flow so that approximately the same amount of gas over time is delivered through each gas injection hole which delivers the same precursor. The diameters of the gas injection holes may also be suitably sized to help ensure that the gas flow rate is about the same through each gas injection hole which flows the same precursor. Mass flow controllers may be disposed upstream of the showerhead assembly 104 so that the flow rate of each precursor to the gas plenums may be adjusted and thereby control the precursor stoichiometry of process gas 152. However, under certain conditions, it may also be desirable to increase or decrease the process gas 152 flow rate at various locations along the showerhead face 153.

In one embodiment, shown in quadrant I, larger concentric gas injection holes 503 having larger diameters D1 and D2 than the corresponding diameters of concentric gas injection holes 502 may be used to increase gas flow rates near the outer perimeter 504 of the showerhead assembly 104 to help compensate for gas flow anomalies which may exist near the annular exhaust channel 105 and outer edges of the substrate carrier 114. For example, the vacuum of the annular exhaust channel 105 may deplete the process gas 152 near outer perimeter 504 and larger concentric gas injection holes 503 may help compensate for the gas depletion. In one embodiment, the values for larger diameters D1 and D2 may be chosen so that the gap size G1 is increased proportionately so that the relative flow rate between first and second precursor gases 154, 155 does not change.

Quadrant II shows another embodiment which uses a greater hole density (number of holes per unit area) for concentric gas injection holes 502 near the outer perimeter 504 of the showerhead assembly 104 which may help provide more uniform gas distribution over substrates 140. A pitch P is the shortest distance between concentric gas injection holes 502 along the same mixing channel 150, and separation distance X is the shortest distance between concentric gas injection holes 502 disposed in adjacent mixing channels 150. The pitch P may be changed to increase or decrease the hole density over desired areas of the showerhead assembly 104. In the present embodiment, the pitch P is decreased to increase the hole density near outer perimeter 504 while separation distance X remains unchanged. In other embodiments, separation distance X and/or the dimensions of the gas channels 501 may also be changed to increase or decrease the hole density. In one embodiment, the ratio of the pitch P near outer perimeter 504 to a normal pitch P away from outer perimeter 504 may range from about 1:1 to about 0.5:1.

In yet another embodiment, shown in quadrant III, concentric gas injection holes 506 may be used to increase the flow rate of one precursor gas relative to another to help achieve the desired gas flow, gas distribution and/or gas stoichiometry across showerhead face 153. In this embodiment, only diameter D1 of first gas injection hole 156 is increased relative to concentric gas injection holes 502. In another embodiment, only diameter D2 of second gas injection hole 157 may be increased relative to concentric gas injection holes 502. In other embodiments, the concentric gas injection hole 502 diameters and hole densities may be varied as desired across showerhead assembly 104. The embodiments shown in FIG. 6 and described herein may be combined and used with other embodiments described herein for showerhead assembly 104.

The previous showerhead assembly 104 embodiments described herein for MOCVD applications may be adapted for use in another deposition technique known as hydride vapor phase epitaxy (HVPE). The HVPE process offers several advantages in the growth of some Group III-V films, GaN in particular, such as high growth rate, relative simplicity, and cost effectiveness. In this technique, the growth of GaN proceeds due to the high temperature, vapor phase reaction between gallium chloride (GaCl) and ammonia (NH₃). The ammonia may be supplied from a standard gas source, while the GaCl is produced by passing a hydride-containing gas, such as HCl, over a heated liquid gallium supply. The two gases, ammonia and GaCl, are directed towards a heated substrate where they react to form an epitaxial GaN film on the surface of the substrate. In general, the HVPE process may be used to grow other Group III-nitride films by flowing a hydride-containing gas (such as HCl, HBr, or HI) over a Group III liquid source to form a Group III-halide gas, and then mixing the Group III-halide gas with a nitrogen-containing gas such as ammonia to form a Group III-nitride film.

In one embodiment, the gas delivery system 125 may comprise a heated source boat (not shown) external to chamber 102. The heated source boat may contain a metal source (e.g., Ga) which is heated to the liquid phase, and a hydride-containing gas (e.g., HCl) may flow over the metal source to form a Group III-halide gas, such as GaCl. The Group III-halide gas and a nitrogen-containing gas, such as NH₃, may then be delivered to first and second plenums 144, 145 of showerhead assembly 104 via supply lines 131, 132 for injection into the processing volume 108 to deposit a Group III-nitride film, such as GaN, on substrates 140. In another embodiment, one or more supply lines 131, 132 may be heated to deliver the precursors from an external heated boat to chamber 102. In another embodiment, an inert gas, which may be hydrogen, nitrogen, helium, argon or combinations thereof, may be flowed between first and second HVPE precursor gases to help keep the precursors separated before reaching the substrates 140. The HVPE precursor gases may also include dopant gases.

In addition to the Group III precursors previously mentioned herein, other Group III precursors may be used with showerhead assembly 104. For example, precursors having the general formula MX₃ where M is a Group III element (e.g., gallium, aluminum, or indium) and X is a Group VII element (e.g., bromine, chlorine or iodine) may also be used (e.g., GaCl₃). Components of the gas delivery system 125 (e.g., bubblers, supply lines) may be suitably adapted to deliver the MX₃ precursors to showerhead assembly 104.

While the foregoing is directed to embodiments of the present invention, other and further embodiments of the invention may be devised without departing from the basic scope thereof, and the scope thereof is determined by the claims that follow.

1. A showerhead apparatus comprising:
a first plenum for a first precursor gas;
a second plenum for a second precursor gas; and
a plurality of inner and outer injection holes wherein the inner injection holes are disposed within the boundaries of the outer injection holes, the inner injection holes in fluid communication with the first plenum and the outer injection holes in fluid communication with the second plenum.

2. The apparatus of claim 1, further comprising a plurality of inner gas conduits through which the first precursor gas is supplied for injection through the inner injection holes and a plurality of outer gas conduits through which the second precursor gas is supplied for injection through the outer injection holes.

3. The apparatus of claim 2, wherein each of the inner gas conduits has an outer gas conduit that is concentrically arranged therewith.

4. The apparatus of claim 3, wherein the inner and outer gas conduits have a cylindrical configuration.

5. The apparatus of claim 3, wherein at least one of the inner and outer gas conduits have a conical configuration.

6. The apparatus of claim 1, further comprising mixing channels defined on a side of the showerhead that faces a substrate processing volume, wherein the first precursor gas and the second precursor gas are injected through the inner and outer injection holes into the mixing channels.

7. The apparatus of claim 6, wherein the mixing channels have a straight and parallel configuration.

8. The apparatus of claim 7, wherein the inner and outer injection holes are staggered between adjacent mixing channels.

9. The apparatus of claim 6, wherein the mixing channels have a spiral configuration.

10. The apparatus of claim 6, wherein the mixing channels have a concentric configuration.

11. The apparatus of claim 1, wherein a mixing zone is defined separately for each pair of inner and outer injection holes on a side of the showerhead that faces a substrate processing volume.

12. The apparatus of claim 11, wherein the mixing zone has a conical configuration.

13. The apparatus of claim 11, wherein mixing zones defined for multiple pairs of inner and outer injection holes are arranged in an x-y grid pattern.

14. The apparatus of claim 13, further comprising heat exchanging channels arranged in an x-y grid pattern in between the mixing zones.

15. A showerhead apparatus comprising:
a plurality of precursor mixing channels defined on a side of the showerhead that faces a substrate processing volume;
a plurality of first injection holes through which a first precursor gas is injected into the precursor mixing channels; and
a plurality of second injection holes through which a second precursor gas is injected into the precursor mixing channels,
wherein each of the first injection holes has a second injection hole that is disposed within the boundary of the first gas injection hole.

16. The apparatus of claim 15, wherein each of the first injection holes has a second injection hole that is concentrically arranged therewith.

17. The apparatus of claim 15, wherein the first injection holes have the same hole diameters and the second injection holes have the same hole diameters.

18. The apparatus of claim 15, wherein the first injection holes have different hole diameters, such that the hole diameters are larger at hole positions closer to the outer periphery of the showerhead apparatus.

19. The apparatus of claim 15, wherein the first and second injection holes have a greater density closer to the outer periphery of the showerhead apparatus.

20. The apparatus of claim 15, further comprising heat exchanging channels formed on the side of the showerhead apparatus that faces the substrate processing volume.

21. The apparatus of claim 20, wherein the heat exchanging channels have a plurality of walls that extend toward the substrate processing volume and define the precursor mixing channels.

22. The apparatus of claim 21, wherein the precursor mixing channels and the heat exchanging channels have a straight and parallel configuration.

23. The apparatus of claim 21, wherein the precursor mixing channels and the heat exchanging channels have a spiral configuration.

24. The apparatus of claim 21, wherein the precursor mixing channels and the heat exchanging channels have a concentric configuration.

25. The apparatus of claim 20, further comprising one or more temperature sensors for measuring the temperature of the showerhead, wherein the flow rate and temperature of heat exchanging fluid that flows through the heat exchanging channels is controlled based on the measured temperature.

26. The apparatus of claim 15, wherein the first precursor gas comprises a Group III precursor gas and the second precursor gas comprises a Group V precursor gas.

27. The apparatus of claim 26, wherein the first and second precursor gases comprise HVPE precursor gases.

28. The apparatus of claim 26, wherein the first and second precursor gases comprise MOCVD precursor gases.

29. The apparatus of claim 26, wherein the first and second precursor gases comprise precursor gases having the general formula MX₃ and M includes one of gallium, aluminum or indium and X includes one of chlorine, bromine, or iodine.

30. The apparatus of claim 26, wherein the first and second precursor gases comprise plasma species.

31. A showerhead apparatus comprising:
a first plenum for a first precursor gas;
a plurality of first gas conduits through which the first precursor gas is supplied from the first plenum to a precursor mixing zone;
a second plenum for a second precursor gas; and
a plurality of second gas conduits through which the second precursor gas is supplied from the second plenum to the precursor mixing zone,
wherein each of the first gas conduits has a second gas conduit that is disposed within the boundary of the first gas conduit.

32. The apparatus of claim 31, wherein each of the first gas conduits has a second gas conduit that is concentrically arranged therewith.

33. The apparatus of claim 31, wherein the first and second gas conduits have a cylindrical configuration.

34. The apparatus of claim 31, wherein at least one of the first and second gas conduits have a conical configuration.

35. The apparatus of claim 31, further comprising heat exchanging channels formed on the side of the showerhead apparatus that faces the substrate processing volume.

36. The apparatus of claim 35, wherein the heat exchanging channels have a plurality of walls that extend toward the substrate processing volume and define the precursor mixing zone.

37. The apparatus of claim 36, wherein the heat exchanging channels have a straight and parallel configuration.

38. The apparatus of claim 36, wherein the precursor mixing channels and the heat exchanging channels have a spiral configuration.

39. The apparatus of claim 36, wherein the precursor mixing channels and the heat exchanging channels have a concentric configuration.

40. The apparatus of claim 36, further comprising one or more temperature sensors for measuring the temperature of the showerhead, wherein the temperature and flow rate of heat exchanging fluid that flows through the heat exchanging channels is controlled based on the measured temperature.

41. The apparatus of claim 31, wherein a mixing zone is defined separately for each concentrically arranged pair of first and second gas conduits on a side of the showerhead that faces a substrate processing volume.
